(19) United States
(12) Patent Application Publication
(10) Pub. No.: US 2002/0076506 A1
(43) Pub. Date: Jun. 20, 2002

(54) Plasma enhanced polymer deposition onto fixtures

(76) Inventors: John D. Affinito, Tucson, AZ (US); Gordon L. Graff, West Richland, WA (US); Mark E. Gross, Pasco, WA (US)

Correspondence Address: Killworth, Gottman, Hagan & Schaeff, L.L.P., One Dayton Centre, Suite 500, Dayton, OH, 45402-2023, US

(21) Appl. No.: 09/811,873

(22) Filed: Mar. 19, 2001

Related U.S. Application Data
(63) Continuation-in-part of application No. 09/212,774, filed on Dec. 16, 1998.

(51) Int. Cl. C23C 16/00

(52) U.S. Cl. 427/569; 427/255.28

(57) ABSTRACT

A method for conformally coating a fixture in a vacuum chamber. The method includes flash evaporating a polymer precursor forming an evaporate, passing the evaporate to a glow discharge electrode creating a glow discharge polymer precursor plasma from the evaporate, and cryocondensing the glow discharge polymer precursor plasma on the fixture as a condensate and crosslinking the condensate thereon, the crosslinking resulting from radicals created in the glow discharge plasma.

### FIELD OF THE INVENTION

This application is a continuation in part of application Ser. No. 09/212,774, filed Dec. 16, 1998, entitled “Plasma Enhanced Polymer Deposition Onto Fixtures.”

The present invention relates generally to a method of making plasma polymerized films on a fixture.

As used herein, a fixture is a discrete item. Examples include, but are not limited to, plumbing fixtures, cabinetry fixtures, tools, optical fixtures including reflectors, light covers, solar collectors and combinations thereof, which are clearly distinct from a continuous item, such as for example, a sheet, wire, or rope.

As used herein, the term “(meth)acrylic” is defined as “acrylic or methacrylic.” Also, “(meth)acrylate” is defined as “acrylate or methacrylate.”

As used herein, the term “cryocondense” and forms thereof refers to the physical phenomenon of a phase change from a gas phase to a liquid phase upon the gas contacting a surface having a temperature lower than a dew point of the gas.

As used herein, the term “polymer precursor” includes monomers, oligomers, and resins, and combinations thereof. As used herein, the term “monomer” is defined as a molecule of simple structure and low molecular weight that is capable of combining with a number of like or unlike molecules to form a polymer. Examples include, but are not limited to, simple acrylate molecules, for example, hexanedioldiacrylate, and tetraethyleneglycoldiacrylate, styrene, methyl styrene, and combinations thereof. The molecular weight of monomers is generally less than 1000, while for fluorinated monomers, it is generally less than 2000. Substructures such as CH₃, t-butyl, and CN can also be included. Monomers may be combined to form oligomers and resins, but do not combine to form other monomers.

As used herein, the term “oligomer” is defined as a compound molecule of at least two monomers that can be cured by radiation, such as ultraviolet, electron beam, or x-ray, glow discharge ionization, and spontaneous thermally induced curing. Oligomers include low molecular weight resins. Low molecular weight is defined herein as about 1000 to about 20,000 exclusive of fluorinated monomers. Oligomers are usually liquid or easily liquifiable.

Oligomers do not combine to form monomers.

As used herein, the term “resin” is defined as a compound having a higher molecular weight (generally greater than 20,000) which is generally solid with no definite melting point.

Examples include, but are not limited to, polystyrene resin, epoxy polyamine resin, phenolic resin, and acrylic resin (for example, polymethylmethacrylate), and combinations thereof.

### BACKGROUND OF THE INVENTION

The basic process of flash evaporation is described in U.S. Pat. No. 4,954,371, herein incorporated by reference. This basic process may also be referred to as polymer multi-layer (PML) flash evaporation. Briefly, a radiation polymerizable and/or cross linkable material is supplied at a temperature below a decomposition temperature and polymerization temperature of the material. The material is atomized to droplets having a droplet size ranging from about 1 to about 50 microns. An ultrasonic atomizer is generally used. The droplets are then flash vaporized, under vacuum, by contact with a heated surface above the boiling point of the material, but below the temperature which would cause pyrolysis. The vapor is cryocondensed on a substrate, then radiation polymerized or cross linked as a very thin polymer layer. The material may include a base monomer or mixture thereof, cross-linking agents and/or initiating agents. A disadvantage of the flash evaporation method with radiation cross linking is that it requires two sequential steps, cryocondensation followed by curing or cross linking, that are both spatially and temporally separate. A disadvantage of this radiation crosslinking method is the time between cryocondensation and curing permitting the cryocondensed monomer to flow or run, especially on fixtures having irregular non-flat geometry, leading to non-uniformity of coating (FIG. 1a) so that the coating surface 150 is geometrically different from the substrate surface 160. Reducing surface temperature can reduce the flow somewhat, but should the monomer freeze, then cross linking is adversely affected. Using higher viscosity monomers is unattractive because of the increased difficulty of degassing, stirring, and dispensing of the monomer.

The basic process of plasma enhanced chemical vapor deposition (PECVD) is described in THIN FILM PROCESSES, J. L. Vossen, W. Kern, editors, Academic Press, 1978, Part IV, Chapter IV—1 Plasma Deposition of Inorganic Compounds, Chapter IV—2 Glow Discharge Polymerization, herein incorporated by reference. Briefly, a glow discharge plasma is generated on an electrode that may be smooth or have pointed projections. Traditionally, a gas inlet introduces high vapor pressure monomeric gases into the plasma region wherein radicals are formed so that upon subsequent collisions with the substrate, some of the radicals in the monomers chemically bond or cross link (cure) on the substrate. The high vapor pressure monomeric gases include gases of CH₄, SiH₄, C₂H₆, C₂H₂, or gases generated from high vapor pressure liquid, for example styrene (10 torr at 87.4° F. (30.8° C.)), hexane (100 torr at 60.4° F. (15.8° C.)), tetramethyldisiloxane (10 torr at 82.9° F. (28.3 ° C.)),1,3-dichlorotetramethyldisiloxane (75 torr at 44.6° F.(7.0° C.)), and combinations thereof that may be evaporated with mild controlled heating. Because these high vapor pressure monomeric gases do not readily cryocondense at ambient or elevated temperatures, deposition rates are low (a few tenths of micrometer/min maximum) relying on radicals chemically bonding to the surface of interest instead of cryocondensation. The low deposition rate is not useable in a high rate industrial application. Remission due to etching of the surface of interest by the plasma competes with deposition of the radicals. Lower vapor pressure species have not been used in PECVD because heating the higher molecular weight monomers to a temperature sufficient to vaporize them generally causes a reaction prior to vaporization, or metering of the gas becomes difficult to control, either of which is inoperative.

According to the state of the art of making plasma polymerized films, PECVD and flash evaporation or glow discharge plasma deposition and flash evaporation have not been used in combination. However, plasma treatment of a substrate using glow discharge plasma generator with inorganic compounds has been used in combination with flash evaporation under a low pressure (vacuum) atmosphere as reported in J. D. Affinito, M. E. Gross, C. A. Coronado, and P. M. Martin, “Vacuum Deposition Of Polymer Electrolytes On Flexible Substrates,” Proceedings of the Ninth International Conference on Vacuum Web Coating, November 1995, ed. R. Bakish, Bakish Press 1995, pg. 20-36, and as shown in FIG. 1b. In that system, the plasma generator 100 is used to etch the surface 102 of a moving substrate 104 in preparation to receive the monomeric gaseous output from the flash evaporation 106 that cryocondenses on the etched surface 102 and is then passed by a first curing station (not shown), for example electron beam or ultra-violet radiation, to initiate cross linking and curing. The plasma generator 100 has a housing 108 with a gas inlet 110. The gas may be oxygen, nitrogen, water or an inert gas, for example argon, or combinations thereof. Internally, an electrode 112 that is smooth or having one or more pointed projections 114 produces a glow discharge and makes a plasma with the gas which etches the surface 102. The flash evaporator 106 has a housing 116, with a monomer inlet 118 and an atomizing nozzle 120, for example an ultrasonic atomizer. Flow through the nozzle 120 is atomized into particles or droplets 122 which strike the heated surface 124 whereupon the particles or droplets 122 are flash evaporated into a gas that flows past a series of baffles 126 (optional) to an outlet 128 and cryocondenses on the surface 102. Although other gas flow distribution arrangements have been used, it has been found that the baffles 126 provide adequate gas flow distribution or uniformity while permitting ease of scaling up to large surfaces 102. In the method of radiation curing, a curing station (not shown) is located downstream of the flash evaporator 106. The monomer may be an acrylate (FIG. 1b). This system was for planar layer coatings. With radiation curing, the time between deposition and curing permits flow of thicker coating layers leading to non-uniformity of coating on non-uniform surfaces or tilted planar surfaces.

Therefore, there is a need for an apparatus and method for coating fixtures with polymerized layers at a fast rate while avoiding flow of the coating.

### SUMMARY OF THE INVENTION

The present invention is a method of making a plasma polymerized film on a fixture.

More specifically, the method is for making a self-curing polymer layer, especially self-curing PML polymer layer on a fixture. The method relies upon a combination of flash evaporation with plasma enhanced chemical vapor deposition (PECVD) that provides the unexpected improvements of permitting use of low vapor pressure polymer precursor materials in a PECVD process and provides a self curing polymer from a flash evaporation process at a rate surprisingly faster (2 orders of magnitude or more) than standard PECVD deposition rates. The present invention also provides the ability to make a conformal coating on a fixture. Because of rapid self-curing, the polymer precursor has less time to flow and is therefore more uniformly thick.

The method of the present invention includes flash evaporating a liquid polymer precursor forming an evaporate, passing the evaporate to a glow discharge electrode creating a glow discharge polymer precursor plasma from the evaporate, and cryocondensing the glow discharge polymer precursor plasma on a substrate as a condensate and crosslinking the condensate thereon, the crosslinking resulting from radicals created in the glow discharge plasma.

Accordingly, the present invention provides a method combining flash evaporation with glow discharge plasma deposition for polymer coating a fixture.

### BRIEF DESCRIPTION OF THE DRAWINGS

FIG. 1a is a cross section of a prior art combination of a glow discharge plasma generator with inorganic compounds with flash evaporation.

FIG. 1b is a chemical diagram of an acrylate.

FIG. 2a is an illustration of non-conformal coating.

FIG. 2b is an illustration of a conformal coating.

FIG. 3 is a cross section of an apparatus useful in the method of the present invention of combined flash evaporation and glow discharge plasma deposition.

FIG. 3a is a cross section end view of the apparatus of FIG. 3.

FIG. 4 is a cross section of an apparatus wherein the substrate or fixture is the electrode.

FIG. 5 is a cross section of the apparatus wherein a plurality of electrodes surrounds the substrate or fixture.

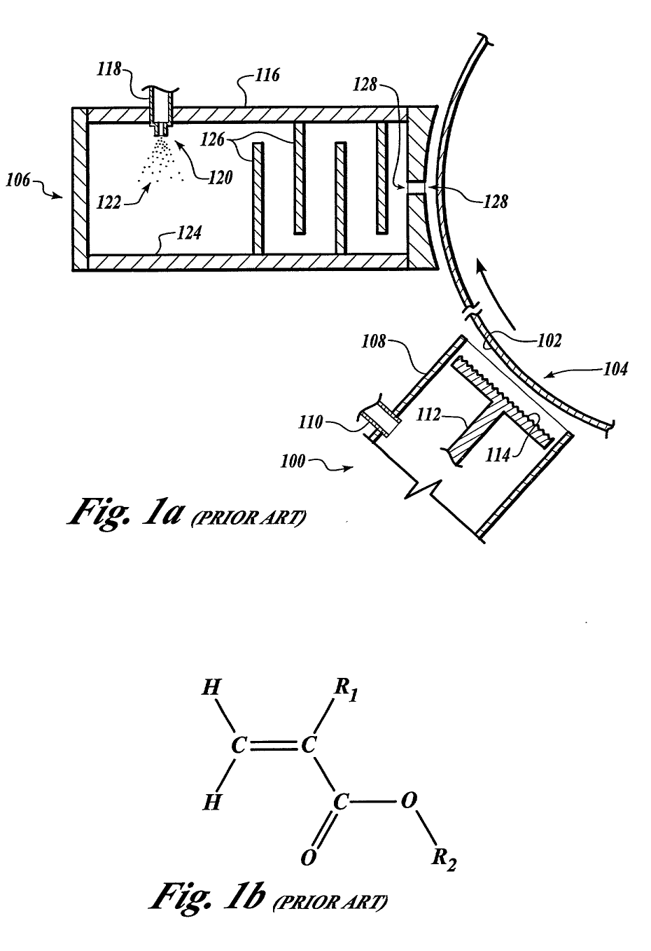

### DETAILED DESCRIPTION OF THE INVENTION

The present invention is a method of conformally coating a fixture. A fixture is a discrete item including, but not limited to, plumbing fixtures for example, faucets, spouts and/or valve handles or knobs, cabinetry fixtures, for example pulls or knobs, hinges, tools (especially hand tools), optical fixtures including reflectors, light covers, solar collectors, and combinations thereof. A fixture is clearly distinct from and excludes a continuous item, such as for example, a sheet, wire, or rope. A conformal coating on a portion of a fixture is illustrated in FIG. 2b wherein a coating surface 150 is geometrically similar to the fixture surface 160.

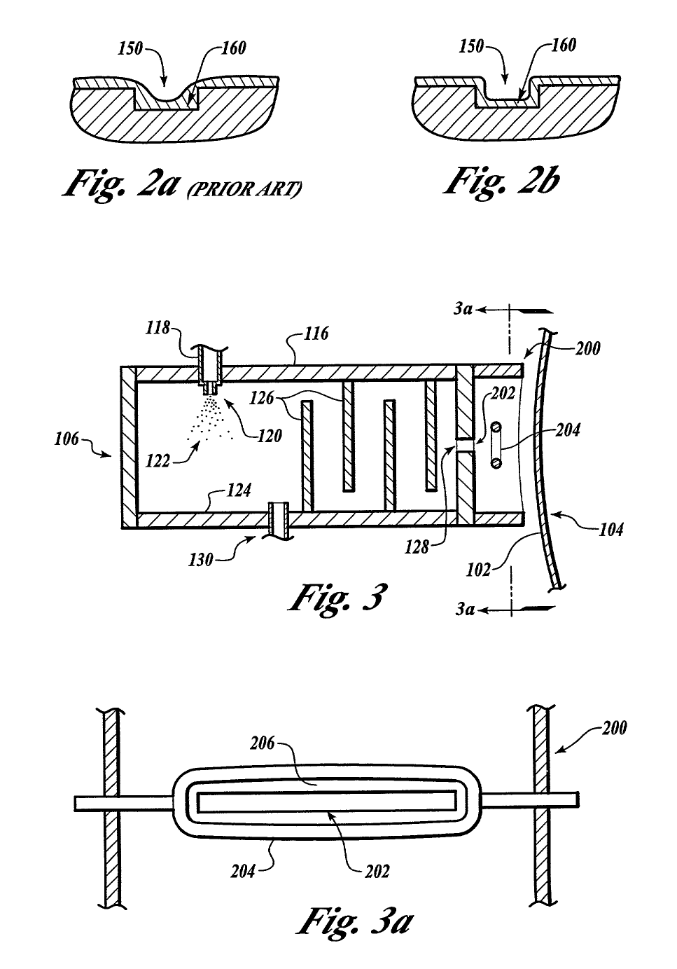

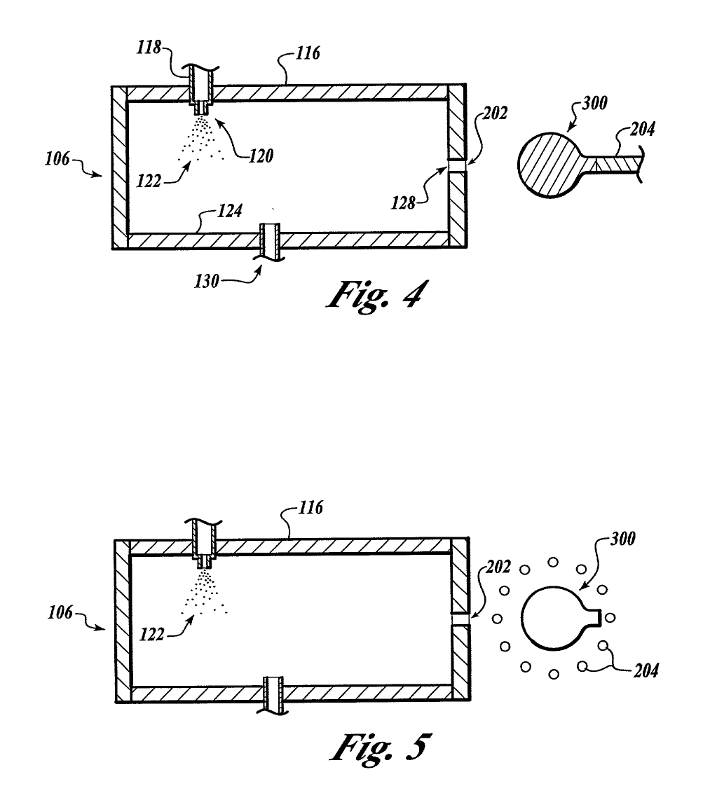

The method of the present invention may be performed using the apparatus of FIG. 3, FIG. 4, or FIG. 5, preferably within a low pressure (vacuum) environment or chamber. Pressures may range from about 10⁻¹ torr to 10⁻⁶ torr, although they can be higher or lower. The flash evaporator 106 has a housing 116, with a polymer precursor inlet 118 and an atomizing nozzle 120. Flow through the nozzle 120 is atomized into particles or droplets 122 which strike the heated surface 124 whereupon the particles or droplets 122 are flash evaporated into a gas or evaporate that flows past a series of baffles 126 to an evaporate outlet 128 and cryocondenses on the surface 102. Cryocondensation on the baffles 126 and other internal surfaces is prevented by heating the baffles 126 and other surfaces to a temperature in excess of a cryocondensation temperature or dew point of the evaporate. Although other gas flow distribution arrangements have been used, it has been found that the baffles 126 provide adequate gas flow distribution or uniformity while permitting ease of scaling up to large surfaces 102. The evaporate outlet 128 directs gas toward a glow discharge electrode 204 creating a glow discharge plasma from the evaporate. In the embodiment shown in FIG. 3, the glow discharge electrode 204 is placed in a glow discharge housing 200 having an evaporate inlet 202 proximate the evaporate outlet 128. In this embodiment, the glow discharge housing 200 and the glow discharge electrode 204 are maintained at a temperature above a dew point of the evaporate. The glow discharge plasma exits the glow discharge housing 200 and cryocondenses on the surface 102 of the fixture 104.

The fixture substrate 104 is generally kept at a temperature below a dew point of the evaporate, typically ambient temperature or cooled below ambient temperature to enhance the cryocondensation rate. In this embodiment, the fixture 104 may be electrically grounded, electrically floating, or electrically biased with an impressed voltage to draw charged species from the glow discharge plasma. If the fixture 104 is electrically biased, it may even replace the electrode 204 and be, itself, the electrode which creates the glow discharge plasma from the polymer precursor gas. Substantially not electrically biased means that there is no impressed voltage although a charge may build up due to static electricity or due to interaction with the plasma.

A preferred shape of the glow discharge electrode 204, is shown in FIG. 2a. In this embodiment, the glow discharge electrode 204 is separate from the fixture 104 and shaped so that evaporate flow from the evaporate inlet 202 substantially flows through an electrode opening 206. Any electrode shape can be used to create the glow discharge, however, the preferred shape of the electrode 204 does not shadow the plasma from the evaporate issuing from the outlet 202 and its symmetry, relative to the polymer precursor exit slit 202 and fixture 104, provides uniformity of the evaporate vapor flow to the plasma is across the width of the fixture while uniformity transverse to the width follows from the substrate motion.

The spacing of the electrode 204 from the fixture 104 is a gap or distance that permits the plasma to impinge upon the fixture. This distance that the plasma extends from the electrode will depend on the evaporate species, electrode 204/fixture 104 geometry, electrical voltage and frequency, and pressure in the standard way as described in detail in ELECTRICAL DISCHARGES IN GASSES, F.M. Penning, Gordon and Breach Science Publishers, 1965, and summarized in THIN FILM PROCESSES, J. L. Vossen, W. Kern, editors, Academic Press, 1978, Part II, Chapter II-1, Glow Discharge Sputter Deposition, both hereby incorporated by reference. Alternatively, the electrode 204 may be a plurality of electrodes distributed throughout the volume of the vacuum chamber defined by the housing 116.

An alternative apparatus also suitable for batch operation is shown in FIG. 4. In this embodiment, the glow discharge electrode 204 is sufficiently proximate a part 300 (fixture) that the part 300 is an extension of or part of the electrode 204. Moreover, the part is below a dew point to allow cryocondensation of the glow discharge plasma on the part 300 and thereby coat the part 300 with the polymer precursor condensate and self cure into a polymer layer.

Sufficiently proximate may be connected to, resting upon, in direct contact with or separated by a gap or distance that permits the plasma to impinge upon the fixture. This distance that the plasma extends from the electrode will depend on the evaporate species, electrode 204/fixture 104 geometry, electrical voltage and frequency, and pressure in the standard way as described in ELECTRICAL DISCHARGES IN GASSES, F.M. Penning, Gordon and Breach Science Publishers, 1965, hereby incorporated by reference. The fixture 104 may be stationary or moving during cryocondensation. Moving includes rotation and translation and may be employed for controlling the thickness and uniformity of the polymer precursor layer cryocondensed thereon. Because the cryocondensation occurs rapidly, within milli-seconds to seconds, the part may be removed after coating and before it exceeds a coating temperature limit.

Another embodiment for non or marginally electrically conductive fixtures is shown in FIG. 5 wherein electrode elements 204 surround the fixture 104.

In operation, the method of the invention includes flash evaporating a liquid polymer precursor forming an evaporate, passing the evaporate to a glow discharge electrode creating a glow discharge polymer precursor plasma from the evaporate, and cryocondensing the glow discharge polymer precursor plasma on a fixture 104 as a condensate and crosslinking the condensate thereon, the crosslinking resulting from radicals created in the glow discharge plasma.

The flash evaporating may be performed by supplying a continuous liquid flow of the polymer precursor into a vacuum environment at a temperature below both the decomposition temperature and the polymerization temperature of the polymer precursor, continuously atomizing the polymer precursor into a continuous flow of droplets, and continuously vaporizing the droplets by continuously contacting the droplets on a heated surface having a temperature at or above a boiling point of the liquid polymer precursor, but below a pyrolysis temperature, forming the evaporate. The droplets typically range in size from about 1 micrometer to about 50 micrometers, but they could be smaller or larger.

Alternatively, the flash evaporating may be performed by supplying a continuous liquid flow of the polymer precursor into a vacuum environment at a temperature below both the decomposition temperature and the polymerization temperature of the polymer precursor, and continuously directly vaporizing the liquid flow of the polymer precursor by continuously contacting the liquid polymer precursor on a heated surface having a temperature at or above the boiling point of the liquid polymer precursor, but below the pyrolysis temperature, forming the evaporate. This may be done using the vaporizer disclosed in U.S. Pat. Nos. 5,402,314, 5,536,323, and 5,711,816, which are incorporated herein by reference.

By using flash evaporation, the polymer precursor is vaporized so quickly that reactions that generally occur from heating a liquid polymer precursor to an evaporation temperature simply do not occur. Further, control of the rate of evaporate delivery is strictly controlled by the rate of liquid polymer precursor delivery to the inlet 118 of the flash evaporator 106.

The liquid polymer precursor may be any liquid polymer precursor. However, the polymer precursor may have a low vapor pressure at ambient temperatures so that it will readily cryocondense. The vapor pressure of the polymer precursor material may be less than about 10 torr at 83 ° F. (28.3 ° C.), less than about 1 torr at 83 ° F. (28.3 ° C.), or less than about 10 millitorr at 83 ° F. (28.3 ° C.). For polymer precursors of the same chemical family, polymer precursors with low vapor pressures usually also have higher molecular weight and are more readily cryocondensible than higher vapor pressure, lower molecular weight polymer precursors. Liquid polymer precursors include, but are not limited to, (meth)acrylate polymer precursors, for example tripropyleneglycol diacrylate, tetraethylene glycol diacrylate, tripropylene glycol monoacrylate, caprolactone acrylate, and combinations thereof.

In addition to the evaporate from the liquid polymer precursor, additional gases may be added within the flash evaporator 106 through a gas inlet 130 upstream of the evaporate outlet 128, preferably between the heated surface 124 and the first baffle 126 nearest the heated surface 124. Additional gases may be organic or inorganic for purposes including, but not limited to, ballast, reaction and combinations thereof. Ballast refers to providing sufficient molecules to keep the plasma lit in circumstances of low evaporate flow rate. Reaction refers to chemical reaction to form a compound different from the evaporate. Additional gases include, but are not limited to, group VIII of the periodic table, hydrogen, oxygen, nitrogen, chlorine, bromine, polyatomic gases including for example carbon dioxide, carbon monoxide, water vapor, and combinations thereof. An exemplary reaction is by addition of oxygen gas to the polymer precursor evaporate hexamethylydisiloxane to obtain silicon dioxide.

The present invention provides the ability to make conformal coatings. Because of rapid plasma polymerization, the polymer precursor has less time to flow and is therefore more uniformly thick even under conditions of substrate temperature and deposition rate that would produce non-conformal coatings using conventional deposition with significantly more time between condensation and polymerization.

Multiple layers of materials may be combined using the present invention. For example, as recited in U.S. Pat. Nos. 5,547,508 and 5,395,644, 5,260,095, hereby incorporated by reference, multiple polymer layers, alternating layers of polymer and metal, and other layers may be made with the present invention in the vacuum environment.

While a preferred embodiment of the present invention has been shown and described, it will be apparent to those skilled in the art that many changes and modifications may be made without departing from the invention in its broader aspects. The appended claims are therefore intended to cover all such changes and modifications as fall within the true spirit and scope of the invention.

We claim:

1. A method for plasma enhanced chemical vapor deposition of low vapor pressure polymer precursor materials onto a fixture in a vacuum environment, comprising:
(a) making an evaporate by receiving a plurality of polymer precursor particles of the low vapor pressure polymer precursor materials as a spray into a flash evaporation housing, evaporating the spray on an evaporation surface, and discharging the evaporate through an evaporate outlet;
(b) making a polymer precursor plasma from the evaporate by passing the evaporate proximate a glow discharge electrode; and
(c) cryocondensing the polymer precursor plasma onto the fixture as a condensate, and crosslinking the condensate thereon, the crosslinking resulting from radicals created in the polymer precursor plasma.

2. The method as recited in claim 1, wherein the fixture is proximate the glow discharge electrode and is electrically biased with an impressed voltage.

3. The method as recited in claim 1, wherein the glow discharge electrode is positioned within a glow discharge housing having an evaporate inlet proximate the evaporate outlet, the glow discharge housing and the glow discharge electrode maintained at a temperature above a dew point of the evaporate, the fixture is downstream of the polymer precursor plasma, and is electrically floating.

4. The method as recited in claim 1, wherein the fixture is proximate the glow discharge electrode and is electrically grounded.

5. The method as recited in claim 1, wherein the polymer precursor is selected from the group consisting of (meth)acrylate polymer precursors, and combinations thereof.

6. The method as recited in claim 5, wherein the (meth)acrylate polymer precursor is selected from the group consisting of tripropyleneglycol diacrylate, tetraethylene glycol diacrylate, tripropylene glycol monoacrylate, caprolactone acrylate, and combinations thereof;

7. The method as recited in claim 1, wherein the fixture is cooled.

8. The method as recited in claim 1, further comprising adding an additional gas to the evaporate.

9. The method as recited in claim 8, wherein the additional gas is a ballast gas.

10. The method as recited in claim 8, wherein the additional gas is a reaction gas.

11. A method for conformally coating a fixture in a vacuum chamber, comprising:
(a) flash evaporating a polymer precursor forming an evaporate;
(b) passing the evaporate to a glow discharge electrode creating a glow discharge polymer precursor plasma from the evaporate; and
(c) cryocondensing the glow discharge polymer precursor plasma as a condensate on the fixture and crosslinking the condensate thereon, the crosslinking resulting from radicals created in the glow discharge polymer precursor plasma.

12. The method as recited in claim 11, wherein the fixture is proximate the glow discharge electrode, and is electrically biased with an impressed voltage.

13. The method as recited in claim 11, wherein the glow discharge electrode is positioned within a glow discharge housing having an evaporate inlet proximate the evaporate outlet, the glow discharge housing and the glow discharge electrode maintained at a temperature above a dew point of the evaporate, and the fixture is downstream of the glow discharge polymer precursor plasma, and is electrically floating.

14. The method as recited in claim 11, wherein the fixture is proximate the glow discharge electrode, and is electrically grounded.

15. The method as recited in claim 11, wherein the polymer precursor is selected from the group consisting of (meth)acrylate polymer precursors and combinations thereof.

16. The method as recited in claim 15, wherein the (meth)acrylate polymer precursor is selected from the group consisting of tripropyleneglycol diacrylate, tetraethylene glycol diacrylate, tripropylene glycol monoacrylate, caprolactone acrylate, and combinations thereof.

17. The method as recited in claim 11, wherein the fixture is cooled.

18 The method as recited in claim 11, further comprising adding an additional gas to the evaporate.

19. The method as recited in claim 18, wherein the additional gas is a ballast gas.

20. The method as recited in claim 18, wherein the additional gas is a reaction gas.

21. The method as recited in claim 11, wherein flash evaporating comprises:
(a) supplying a continuous liquid flow of the polymer precursor into a vacuum environment at a temperature below both the decomposition temperature and the polymerization temperature of the polymer precursor;
(b) continuously atomizing the polymer precursor into a continuous flow of droplets; and
(c) continuously vaporizing the droplets by continuously contacting the droplets on a heated surface having a temperature at or above a boiling point of the polymer precursor, but below a pyrolysis temperature, forming the evaporate.

22. The method as recited in claim 21 wherein the droplets range in size from about 1 micrometer to about 50 micrometers.

23. The method as recited in claim 11 wherein flash evaporating comprises:
(a) supplying a continuous liquid flow of the polymer precursor into a vacuum environment at a temperature below both the decomposition temperature and the polymerization temperature of the polymer precursor; and
(b) continuously directly vaporizing the liquid flow of the polymer precursor by continuously contacting the polymer precursor on a heated surface having a temperature at or above a boiling point of the polymer precursor, but below a pyrolysis temperature, forming the composite evaporate.
